(19) United States
(12) Patent Application Publication
(10) Pub. No.: US 2003/0002549 A1
(43) Pub. Date: Jan. 2, 2003

(54) Two-wavelength laser diode, and manufacturing method therefor

(76) Inventor: Myeong Seok Oh, Suwon (KR)

Correspondence Address: Don W. Bulson, Esq., Renner, Otto, Boisselle & Sklar, LLP, 19th Fl., 1621 Euclid Ave., Cleveland, OH, 44115, US

(21) Appl. No.: 10/219,511

(22) Filed: Aug. 15, 2002

Related U.S. Application Data
(62) Division of application No. 09/802,626, filed on Mar. 9, 2001.

(30) Foreign Application Priority Data
May 24, 2000 (KR) 2000-27976
Jan. 11, 2001 (KR) 2001-1559

(51) Int. Cl. H01S 5/00; H01S 3/04; H01S 3/10

(52) U.S. Cl. 372/36; 372/43; 372/23

(57) ABSTRACT

A laser diode is disclosed, in which a laser diode for emitting the beams of a long wavelength and another laser diode for emitting the beams of a short wavelength are sequentially stacked upon a submount, thereby minimizing the gap errors and the position errors for the light emitting points. That is, the distance between the light emitting points can be minimized, and therefore, unlike in the conventional techniques, a separate additional optical component is not required. Accordingly the adjustment of the optical axis is rendered easier, and therefore, the yield is increased, while the assembling cost can be curtailed.

### FIELD OF THE INVENTION

The present invention relates to a laser diode which emits two-wavelength beams. Particularly, the present invention relates to two-wavelength a laser diode in which a laser diode (LD) for emitting the beams of a long wavelength and another laser diode for emitting the beams of a short wavelength are sequentially stacked upon a submount, thereby minimizing the gap errors and the position errors for the light emitting points.

### BACKGROUND OF THE INVENTION

Generally, the laser beams which are used in the CD (compact disk) are infrared beams having a wavelength of about 780 nm, while the laser beams which are used in the DVD (digital video disk) are the red visible light having a wavelength of about 650 nm.

Among the laser diodes which use such laser beams, the laser diodes for reproducing the DVD-ROM and the CD-ROM include: a semiconductor laser for emitting a single wavelength; and a semiconductor laser for emitting two wavelengths as shown in FIGs. 1a and 1b.

In the case where two laser diodes are used as shown in FIG. 1a, the two laser beams of different wavelengths which are emitted from two laser diodes 10 and 20 are merged at a prism 40, and focused at a objective lens 30. The laser beams which are focused by the objective lens 30 are reflected from disk 60, and then, the read again by a photo diode 70.

Meanwhile, as shown in FIG. 1b, in the case where one laser diode emitting laser beams having two wavelengths is used, a semiconductor laser 10A for emitting two wavelengths is formed into a single unitized unit, so that a separate prism 40 would not be required.

As shown in FIG. 2, the laser diode which emits laser beams having a single wavelength includes: an n type GaAs substrate 2 with a contact electrode 1 formed on the bottom thereof; an n type AlGaInP cladding layer 3 stacked upon the substrate 2; an InGaP active layer 4 having a light emitting point and stacked upon the n type AlGaInP cladding layer 3; and a p type InAlP cladding layer 5 having a contact electrode 6 and stacked upon the InGaP active layer 4, whereby a laser diode is formed through a p-n junction.

Meanwhile, the unitized two-wavelength laser diode is roughly classified into: a monolithic type and a hybrid type as shown in FIGS. 3a and 3b.

The monolithic type laser diode is described in U.S. Pat. No. 5,999,553.

As shown in FIG. 3a, the monolithic type laser diode is constituted as follows. That is, two laser diodes 15 and 25 which are mounted on a submount 5 and which have different wavelengths respectively are consolidated upon a substrate 4, so that the gap error range of light emitting points 15A and 25A can be minimized.

If the gap between the two light emitting points is sufficiently small, then the two sets of the laser beams can be focused onto a light receiving part PDIC. Accordingly, the cost for the light pickup can be curtailed, and therefore, the error range of the light emitting points becomes an important factor for the manufacture of the laser diode.

The error range of the light emitting points is decided by the processing error of the semiconductor photo lithography process, while the height of the light emitting points 15A and 25A is decided by the film thickness during the growth of the crystals. Meanwhile, the horizontal positions of the light emitting points are decided to the positions to which the ridges A of the semiconductor laser are formed.

However, in the above described monolithic type laser diode, the two laser diodes 15 and 25 are formed upon the same substrate 4, and they are electrically isolated from each other by etching. Therefore, if a defect occur in one of the laser diodes, then the whole two-wavelength laser diode becomes defective. Further, the two laser diodes have to be grown twice sequentially at the same conditions, and therefore, there is a high probability that the degradation of the characteristics occurs, while the manufacturing cost rises.

Meanwhile, in the hybrid type laser diode as shown in FIG. 3b, two laser diodes 15 and 25 having different wavelengths are separatedly formed upon a substrate, and therefore, the product cost will not be increased. The laser diodes of the different oscillation wavelengths are independently formed, and these are installed on a submount 5, thereby forming a two-wavelength laser diode.

In this hybrid type laser diode, however, the two laser diodes have to be separated by a certain distance, and their light emitting points have to be separated from the ridge by a certain distance, these being the requisite of the laser diodes 15 and 25. Therefore, a separation of at least 150 μm or more is given to the gap between the light emitting points 15A and 25A (the separation distance for the independent action plus the separation distance for preventing degradation of the characteristics), with the result that the drift of the beams is liable to become high. Further, the separation distance between the two light emitting points becomes large compared with the monolithic type laser diode (in which the dispersion errors can be inhibited). Further, the dispersion occurs due to the mechanical errors during the installation of the diodes on the submount. If this dispersion of the light emitting points becomes large, then there are required two photo diodes, with the result that the manufacturing cost rises. Further, in this case, a separate adjusting means is required also at the receiving part.

### SUMMARY OF THE INVENTION

The present invention is intended to overcome the above described disadvantages of the conventional techniques.

Therefore it is an object of the present invention to provide a two-wavelength laser diode in which the semiconductor laser package is packed into a single pack to form a single light path, the gap between two light emitting points of two laser diodes is reduced, and the position errors are minimized.

It is another object of the present invention to provide a two-wavelength laser diode in which two laser diodes are stacked in a simple manner without employing a separate etching process, thereby making the manufacture easy.

In achieving the above objects, the two-wavelength laser diode according to the present invention includes: a submount; a first laser diode formed upon the submount, for emitting beams of a first wavelength; and a second laser diode formed upon the first laser diode, for emitting beams of a second wavelength.

In another aspect of the present invention, the two-wavelength laser diode according to the present invention includes: a submount; a first laser diode formed upon the submount, for emitting beams of a short wavelength;

the first laser diode including: (a) an n type first substrate; (b) an n type first cladding layer formed on the n type first substrate; (c) a first active layer formed upon the n type first cladding layer and having a first light emitting point; (d) a p type second cladding layer and an n type first blocking layer sequentially stacked upon the first active layer; and (e) a p type first cap layer formed upon the first blocking layer;

a second laser diode formed upon the first laser diode, for emitting beams of a long wavelength;

the second laser diode including: (a) an n type second substrate; (b) an n type third cladding layer formed upon the n type second substrate; (c) a second active layer formed upon the n type third cladding layer and having a second light emitting point; (d) a p type fourth cladding layer and an n type second blocking layer sequentially stacked upon the second active layer; and (e) a p type second cap layer formed upon the second blocking layer;

first and second electrodes formed respectively on the bottom of the first substrate and on the top of the first cap layer, for supplying electric currents to the first active layer;

third and fourth electrodes formed respectively on the bottom of the second substrate and on the top of the second cap layer, for supplying electric currents to the second active layer; and

a heat sink formed beneath the submount.

In still another aspect of the present invention, the method for manufacturing a two-wavelength laser diode according to the present invention includes the steps of: (i) preparing a submount; (ii) forming a first laser diode for emitting beams of a short wavelength; (iii) forming a second laser diode for emitting beams of a long wavelength; (iv) attaching the first laser diode onto the top of the submount; (v) attaching the second laser diode onto the top of the first laser diode; and (vi) attaching a heat sink onto the bottom of the submount.

### BRIEF DESCRIPTION OF THE DRAWINGS

The above objects and other advantages of the present invention will become more apparent by describing in detail the preferred embodiments of the present invention with reference to the attached drawings in which:

FIGS. 1a and b are schematic views showing the operations of the general semiconductor laser diodes;

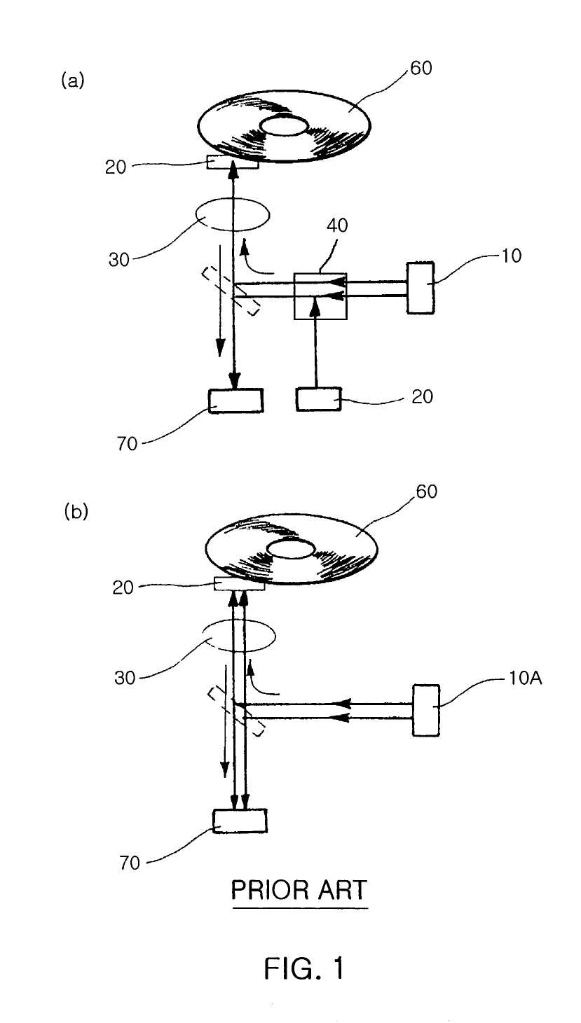

FIG. 2 is a schematic view showing the stacking of the general laser diode;

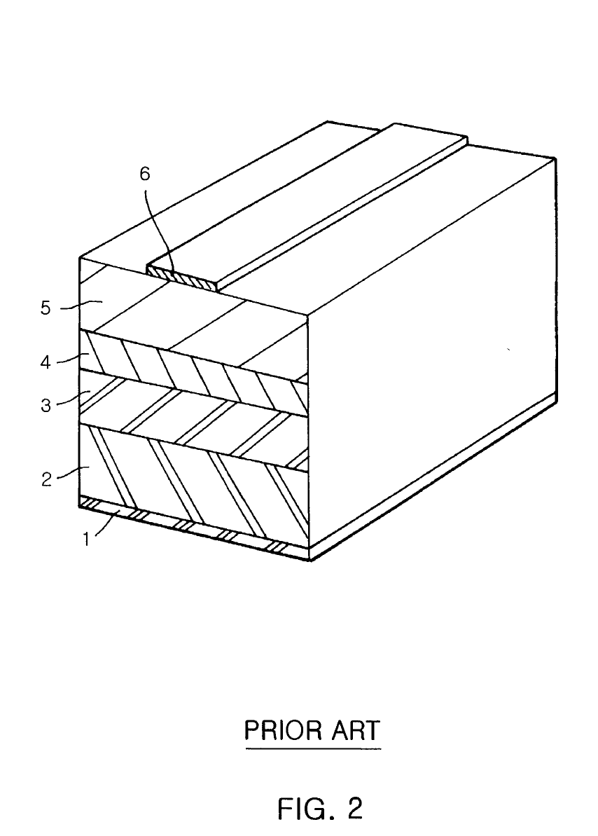

FIGS. 3a and 3b are side views showing the constitution of the conventional two-wavelength laser diode;

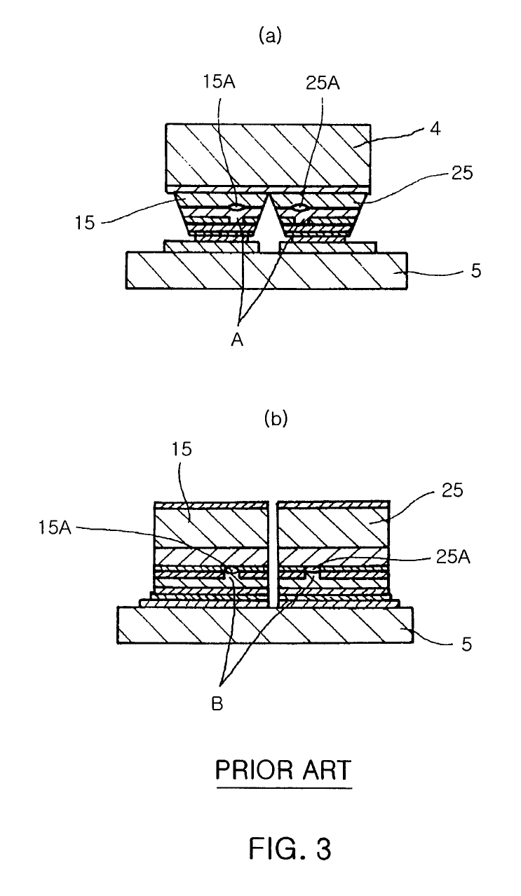

FIG. 4 is a side view showing a preferred embodiment of the two-wavelength laser diode according to the present invention;

FIG. 5 is a plan view showing the electrode formation in the two-wavelength laser diode according to the present invention; and

FIG. 6 is a side view showing another preferred embodiment of the two-wavelength laser diode according to the present invention.

### DETAILED DESCRIPTION OF THE PREFERRED EMBODIMENTS

The present invention will be described in detail referring to the attached drawings.

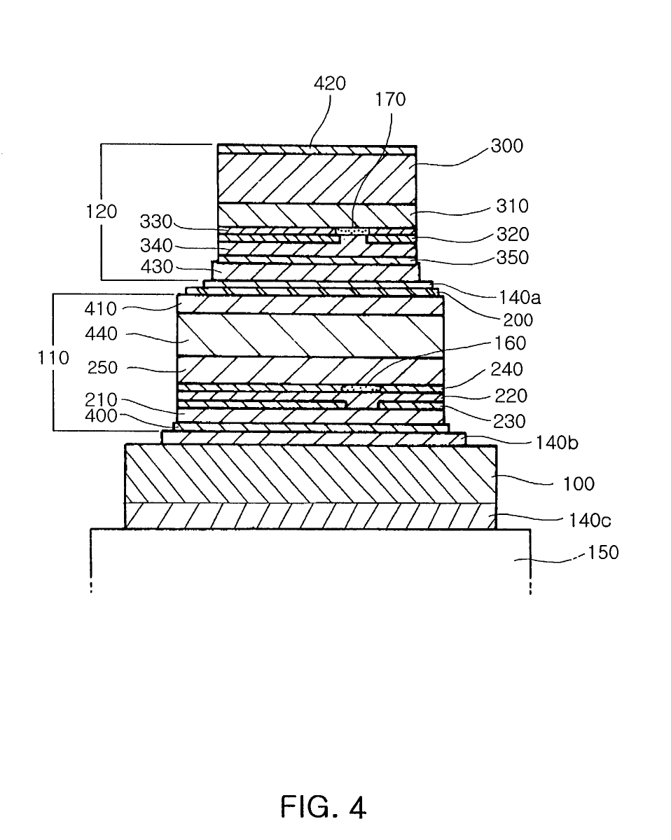

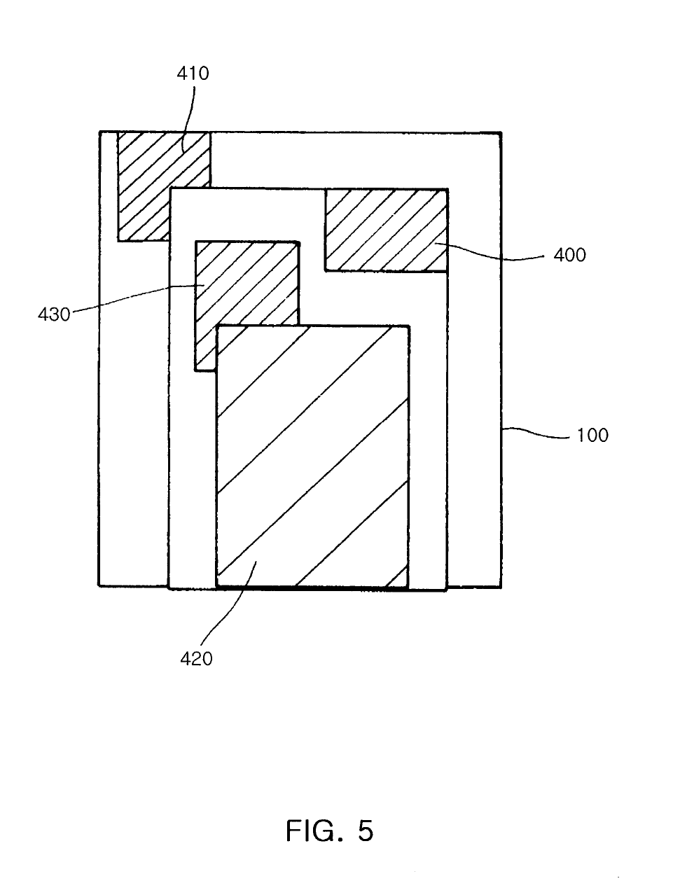

FIG. 4 is a side view showing a preferred embodiment of the two-wavelength laser diode according to the present invention. FIG. 5 is a plan view showing the electrode formation in the two-wavelength laser diode according to the present invention.

The two-wavelength laser diode according to the present invention includes: a submount 100; a first laser diode 110 formed upon the submount 100, for emitting the beams of a short wavelength; and a second laser diode formed upon the first laser diode 110, for emitting the beams of a long wavelength.

The first laser diode 110 which emits the beams of a short wavelength of 650 nm is constituted as follows. That is, an n type AlGaInP first cladding layer 250 is stacked upon an n type GaAs first substrate 440, and an InGaP first active layer 240 is stacked upon then type AlGaInP first cladding layer 250. an AlGaInP second cladding layer 220 and an n-GaAs first blocking layer 230 are stacked on the first active layer 240. Further, a p type GaAs cap layer 210 is stacked upon the first blocking layer 230, and a first light emitting point 160 is formed in the first active layer 240, for emitting the beams of a short wavelength.

Meanwhile, the second laser diode 120 which emits the beams of a long wavelength of 780 nm is constituted as follows. That is, an n type AlGaAs third cladding layer 310 is stacked upon an n type GaAs second substrate 300, and an AlGaAs second active layer 330 is stacked upon the n type third cladding layer 310.

A p type AlGaAs fourth cladding layer 340 and an n-GaAs second blocking layer 320 are stacked upon the second active layer 330, and a p type GaAs second cap layer 350 is stacked upon the second blocking layer 320. Further, a light emitting point 170 is formed in the second active layer 330, for emitting the beams of a long wavelength.

Further, first and second electrodes 400 and 410 supply electric currents to the first active layer 240 which emits the beams of a short wavelength, and these first and second electrodes 400 and 410 are stacked on the top of the first cap layer 210 and on the bottom of the first substrate 440 respectively.

Further, third and fourth electrodes 420 and 430 supply electric currents to the second active layer 330 which emits the beams of a long wavelength, and these third and fourth electrodes 420 and 430 are stacked respectively on the bottom of the second substrate 300 and on the top of the second cap layer 350.

The first laser diode 110 of a short wavelength of 650 nm is generally used for reproducing the DVD-ROM, and the second laser diode 120 of a long wavelength of 780 nm is used for reproducing the CD-ROM. The first laser diode 110 and the second laser diode 120 are attached on the submount 100 by using adhesive means 140a and 140b which are made of a metal Au—Sn, Sn, In) or an epoxy resin. In this case, the first and second light emitting points are positioned on a vertical axis which is perpendicular to the horizontal plane of the submount 100.

The separation between the first and second light emitting points 160 and 170 should be preferably 50-150 μm, and therefore, a separate adjusting component is not required unlike in the conventional method in which a separate adjusting component is required because the gap between the first and second light emitting points 160 and 170 cannot be reduced.

On the bottom of the submount 100, there can be formed a heat sink 150 for dissipating the heat which is generated by the first laser diode 110.

The heat sink 150 is attached on the bottom of the submount through a third adhesive layer 140c which is made of a metal or an epoxy resin so as to improve the thermal conductivity.

Accordingly, on the top of the submount 100, there is stacked the first laser diode 110 of the wavelength of 650 nm, which has a relatively low thermal conductivity and which generates a large amount of heat in the relative terms. In this manner, the heat which is generated from the first laser diode 110 can be effectively removed.

Under this condition, in order to more effectively remove the heat from the first laser diode 110, the first cap layer 210 of the first laser diode 110 is installed adjacently to the submount 100.

That is, the distance from the first light emitting point 160 to the first cap layer 210 is shorter than the distance from the first light emitting point 160 to the first substrate 440. Therefore as described above, the first laser diode 110 is disposed immediately upon the top of the submount 100 and adjacently to the heat sink 150, so that the heat generated from the first light emitting point 160 can be easily dissipated.

In the above case, the distance between the first light emitting point 160 and the submount 100 is about 3-50 μm.

Further, in order to electrically isolate the first laser diode 110 and the second laser diode 120 from each other, there is formed an insulating layer 200 between the first laser diode 110 and the second laser diode 120. Owing to this insulating layer 200, the first and second laser diodes 110 and 120 can be driven in a mutually electrically isolated manner.

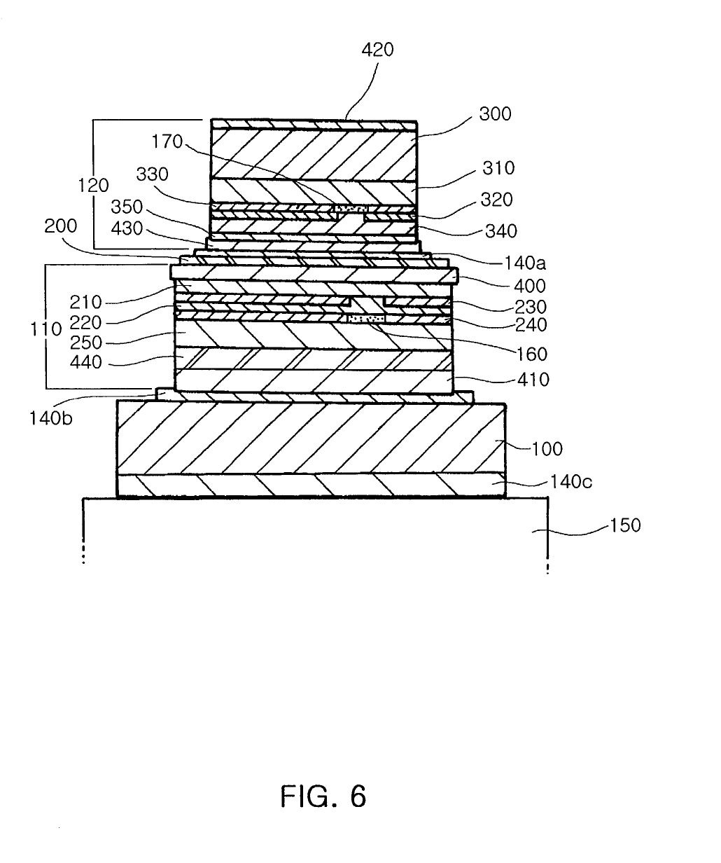

FIG. 6 is a side view showing another preferred embodiment of the two-wavelength laser diode according to the present invention.

Referring to FIG. 6, a p type layer, i.e., a p type GaAs first cap layer 210 of the first laser diode 110 is disposed adjacently to a p type GaAs second cap layer 350 of the second laser diode 120. Further, an n type GaAs first substrate 440 of the first laser diode 110 is disposed adjacently to the submount 100. Except the above described structure, this second embodiment is exactly same as the first embodiment of the present invention.

In this constitution, the distance between the first cap layer 210 and the first light emitting point 160 of the first laser diode 110 is shorter than the distance between the first light emitting point 160 and the first substrate 440. Further, the distance between the second cap layer 350 and the second light emitting point 170 of the second laser diode 120 is shorter than the distance between the second light emitting point 170 and the second substrate 300. For this reason, the distance between the first light emitting point 160 and the second light emitting point 170 can be minimized.

Further, the first and second light emitting points 160 and 170 are positioned on the same vertical axis which is perpendicular to the horizontal plane of the submount 100, and therefore, the distance between the two points is minimized.

Under this condition, the distance between the first and second light emitting points 160 and 170 should be preferably 50-150 μm, and the distance between the first and second light emitting points 160 and 170 can be more minimized in this embodiment than in the first embodiment.

Accordingly, a separate adjusting component is not required unlike the conventional technique in which a separate adjusting component is required because in it the distance between the two points cannot be reduced.

The first and second laser diodes 110 and 120 are attached together by a first adhesive layer 140a like in the first embodiment, while an insulating layer 200 is disposed between the first and second laser diodes 110 and 120 to electrically isolate them from each other.

The laser diode of the present invention constituted as above will now be described as to its action.

As shown in FIGS. 4 to 6, the two-wavelength diode according to the present invention is capable of reproducing two disks, i.e., a DVD-ROM disk and a CD-ROM disk, because there are a first laser diode 110 of a wavelength of 650 nm and a second laser diode 120 of a wavelength of 780 nm.

In each of the laser diodes 110 and 120, if a voltage is supplied to the p-n junction where the cladding layers of the first and second active layers 240 and 330 are stacked, then an electric current flows. Under this condition, the electrons of the n region and the holes of the p region move toward the opposite regions to form reunions, with the result that induced emissions occur. Owing to the induced emissions, light beams of different wavelengths are emitted from the first and second light emitting points 160 and 170 of the first and second active layers 240 and 330.

That is, the first light emitting point 160 emits light beams of a wavelength of 650 nm, while the second light emitting point 170 emits light beams of a wavelength of 780 nm.

Under this condition, the light beams of the first laser diode 110 have a relatively shorter wavelength, and therefore, a relatively large amount of heat is generated from it. Therefore, the first laser diode 110 is installed adjacently to the heat sink 150, so that the distance between the first laser diode 110 and the heat sink 150 can be minimized, thereby effectively dissipating the heat from the first laser diode 110 owing to an efficient thermal conduction from the diode 110 to the heat sink 150.

Meanwhile, the second laser diode 120 of a wavelength of 780 nm is unitizingly attached onto the first laser diode 110 of a wavelength of 650 nm through the first adhesive layer 140a, the adhesive layer 140a being made of an epoxy resin. The first and second laser diodes 110 and 120 are electrically isolated from each other by an insulating layer 200, and their electrodes are connected to an external power source.

Under this condition, if a power is supplied, the first and second laser diodes 110 and 120 respectively emit two sets of light beams of different wavelengths in which the position errors are minimized. Therefore, without employing a separate light receiving device, a DVD-ROM disk and a CD-ROM disk can be read.

According to the present invention as described above, a laser diode having a short wavelength and another laser diode having a long wavelength are unitizingly stacked upon a single submount. Therefore, the distance between the light emitting points can be minimized, and therefore, unlike in the conventional techniques, a separate additional optical component is not required. Accordingly the adjustment of the optical axis is rendered easier, and therefore, the yield is increased, while the assembling cost can be curtailed.

Further, a heat sink is installed adjacently to the laser diode of the short wavelength, and particularly, the p type layer of the laser diode of the short wavelength is made nearer to the heat sink. Accordingly, the distance between the heat sink and the light emitting point of the laser diode of the short wavelength can be minimized, and therefore, the heat which is generated from the laser diode of the short wavelength can be efficiently dissipated. As a result, the deterioration of the product quality can be prevented, and consequently, the life expectancy of the product can be extended.

In the above, the present invention was described based on the specific preferred embodiments and the attached drawings, but it should be apparent to those ordinarily skilled in the art that various changes and modifications can be added without departing from the spirit and scope of the present invention which will be defined in the appended claims.

What is claimed is:

1. A two-wavelength laser diode comprising:
a submount;
a first laser diode formed upon said submount, for emitting beams of a first wavelength; and
a second laser diode formed upon said first laser diode, for emitting beams of a second wavelength.

2. The two-wavelength laser diode as claimed in claim 1, wherein said first laser diode comprises:
(a) an n type first substrate;
(b) an n type first cladding layer formed upon said n type first substrate;
(c) a first active layer formed upon said n type first cladding layer and having a first light emitting point;
(d) ap type second cladding layer and an type first blocking layer sequentially stacked upon said first active layer; and
(e) a p type first cap layer formed upon said first blocking layer.

3. The two-wavelength laser diode as claimed in claim 1, wherein said second laser diode comprises:
(a) an n type second substrate;
(b) an n type third cladding layer formed upon said n type second substrate;
(c) a second active layer formed upon said n type third cladding layer and having a second light emitting point;
(d) a p type fourth cladding layer and an n type second blocking layer sequentially stacked upon said second active layer; and
(e) a p type second cap layer formed upon said second blocking layer.

4. The two-wavelength laser diode as claimed in claim 1, wherein said first wavelength is 650 nm, and said second wavelength is 780 nm.

5. A two-wavelength laser diode comprising:
a submount;
a first laser diode formed upon said submount, for emitting beams of a short wavelength;
said first laser diode including, (a) an n type first substrate, (b) an n type first cladding layer formed upon said n type first substrate, (c) a first active layer formed upon said n type first cladding layer and having a first light emitting point, (d) a p type second cladding layer and an n type first blocking layer sequentially stacked upon said first active layer, and (e) a p type first cap layer formed upon said first blocking layer,
a second laser diode formed upon said first laser diode, for emitting beams of a long wavelength;
said second laser diode including, (a) an n type second substrate, (b) an n type third cladding layer formed upon said n type second substrate, (c) a second active layer formed upon said n type third cladding layer and having a second light emitting point, (d) a p type fourth cladding layer and an n type second blocking layer sequentially stacked upon said second active layer, and (e) a p type second cap layer formed upon said second blocking layer,
first and second electrodes formed on a bottom of said first substrate and on a top of said first cap layer respectively, for supplying electric currents to said first active layer;
third and fourth electrodes formed respectively on a bottom of said second substrate and on a top of said second cap layer, for supplying electric currents to said second active layer; and
a heat sink formed under said submount.

6. The two-wavelength laser diode as claimed in claim 5, wherein said n type second substrate of said second laser diode is formed upon said first cap layer of said first laser diode.

7. The two-wavelength laser diode as claimed in claim 5, wherein said second cap layer of said second laser diode is formed upon said first cap layer of said first laser diode.

8. The two-wavelength laser diode as claimed in claim 5, wherein there is a distance of 50-150 μm between said first light emitting point and said second light emitting point.

9. The two-wavelength laser diode as claimed in claim 5, wherein there is a distance of 3-50 μm between said first light emitting point and said submount.

10. The two-wavelength laser diode as claimed in claim 5, further comprising: a plurality of attachment means formed between said second laser diode, said submount and said heat sink respectively.

11. The two-wavelength laser diode as claimed in claim 5, further comprising: an insulating layer formed between said first and second laser diodes, for electrically isolating said first and second laser diodes from each other.

12. The two-wavelength laser diode as claimed in claim 5, wherein said first and second light emitting points are positioned on a same vertical axis perpendicular to a horizontal plane of said submount.

13. A method for manufacturing a two wavelength laser diode, comprising the steps of:
(i) preparing a submount;
(ii) forming a first laser diode for emitting beams of a short wavelength;
(iii) forming a second laser diode for emitting beams of a long wavelength;
(iv) attaching said first laser diode onto a top of said submount;
(v) attaching said second laser diode onto a top of said first laser diode; and
(vi) attaching a heat sink onto a bottom of said submount.

14. The method as claimed in claim 13, wherein at the steps (iv), (v) and (vi), the attachments are carried out by using a metal.

15. The method as claimed in claim 13, wherein at the steps (iv), (v) and (vi), the attachments are carried out by using an epoxy resin.

16. The method as claimed in claim 13, wherein the step (iii) further comprises a step of forming an insulating layer upon said first laser diode.
